(19) United States
(12) Patent Application Publication
(10) Pub. No.: US 2013/0021066 A1
(43) Pub. Date: Jan. 24, 2013

(54) Method and Apparatus for Driving a Display Device with Charge Sharing

(71) Applicant: Ji-Ting Chen, Hsinchu County (TW)

(72) Inventor: Ji-Ting Chen, Hsinchu County (TW)

(21) Appl. No.: 13/342,202

(22) Filed: Jan. 3, 2012

(30) Foreign Application Priority Data
Jul. 22, 2011 (TW) 100125941

(51) Int. Cl. H03K 3/00

(52) U.S. Cl. 327/108

(57) ABSTRACT

A driving device for a display device is disclosed. The driving device includes a first output buffer, for generating a first source driving signal at a first output end; a second output buffer, for generating a second source driving signal at a second output end; and an electric charge storage unit, including a voltage sensing end coupled to the first output buffer and the second output buffer, for receiving and storing electric charges released by the first output buffer via the voltage sensing end when a level of the first source driving signal decreases, and for outputting the electric charges to the second output buffer via the voltage sensing end when a level of the second source driving signal increases.

### BACKGROUND OF THE INVENTION

1. Field of the Invention

The present invention relates to a driving device and a driving method used in a display device, and more particularly, to a driving device and a driving method capable of storing and outputting electric charges according to voltage variations of output buffers.

2. Description of the Prior Art

Comparing with a cathode ray tube (CRT) display device, a liquid crystal display (LCD) device is provided with advantages of lighter weight, less power consumption and less radiation contamination, and has been widely applied to various information technology (IT) products, such as computer systems, mobile phones, notebooks, digital cameras and personal digital assistants (PDAs). An operating principle of the LCD device is based on a fact that different twisted states of liquid crystals result in different polarizations and refractions on light passing through the liquid crystals. Thus, the different twisted states of the liquid crystals can be used to control an amount of the light emitted from the LCD device, so as to produce light outputs at various brightnesses, and diverse gray levels of red, green and blue light.

With growing environmental consciousness, industries have devoted efforts to develop products with low power consumption, where most products produced by IT industries are electronic devices consuming electricity. Taking the LCD device as an example, even though a standby LCD device consumes only a few watts of electric power, an operating LCD device may consume tens to hundreds of watts of electric power according to a size of the operating LCD device. In general, a source driver of an LCD device according to the prior art comprises a charging sharing unit, for reusing electric charges, to reduce power consumption.

Please refer to FIG. 1, which is a schematic diagram of a source driver 10 of an LCD device according to an example of the prior art. The source driver 10 is utilized in the LCD device, for generating a source driving signal, to drive a panel of the LCD device, so as to control operation of pixels of the panel. The source driver 10 includes a first output buffer 100 and a second output buffer 102 which include a first output end 104 and a second output end 106, respectively. The first output buffer 102 is coupled between a high voltage source V_H and an intermediate voltage source V_M; the second output buffer 104 is coupled between the intermediate voltage source V_M and a low voltage source V_L. The first output buffer 102 uses voltages provided by the high voltage source V_H and the intermediate voltage source V_M, for outputting a first source driving signal SD_sig1 to the panel of the LCD device via the first output end 104 according to a received frame signal FRM1, to control the operation of the pixels of the panel. Similarly, the second output buffer 104 uses the voltages provided by the intermediate voltage source V_M and the low voltage source V_L, for outputting a second source driving signal SD_sig2 to the panel of the LCD device via the second output end 106 according to a received frame signal FRM2, to control the operation of the pixels of the panel.

In detail, about operation of the source driver 10, please refer to FIG. 2, which is a schematic diagram of variations of the source driving signals shown in FIG. 1. When the first output buffer 100 and the second output buffer 102 need to reduce the first source driving signal SD_sig1 and increase the second source driving signal SD_sig2 at the same time according to the frame signals FRM1 and FRM2, respectively, the second output buffer 102 receives electric charges released by the first output buffer 100, for increase the second source driving signal SD_sig2. In other words, the first output buffer 100 releases the electric charges when reducing the first source driving signal SD_sig1; the second output buffer 102 absorbs the electric charges when increasing the second source driving signal SD_sig2. That is, the levels of the source driving signals relate to an amount of the electric charges stored in the output buffers. Therefore, the second output buffer 102 reuses the electric charges released by the first output buffer 100 according to charge sharing provided by the source driver 10, and does not need to obtain the electric charges from the intermediate voltage source V_M, such that power consumption of the source driver 10 is reduced.

On the other hand, the source driver 10 needs to maintain a voltage of the intermediate voltage source V_M within a specific range such that the first output buffer 100 and the second output buffer 102 can output the source driving signals with the same amplitude. Therefore, when the first output buffer 100 needs to reduce the first source driving signal SD_sig1 and the second output buffer 102 does not need to increase the second source driving signal SD_sig2, the second output buffer 102 can only export the electric charges released by the first output buffer 100 to the ground, and the electricity is wasted. For example, please refer to FIG. 3, which is a schematic diagram of variations of the source driving signals shown in FIG. 1. The first output buffer 100 and the second output buffer 102 need to reduce the first source driving signal SD_sig1 and the second source driving signal SD_sig2 at the same time according to the frame signals FRM1 and FRM2, respectively. The first output buffer 100 releases the electric charges. Since the second output buffer 102 does not need the electric charges and the voltage of the intermediate voltage source V_M must be maintained within the specific range, the second output buffer 102 can only export the electric charges to the ground. In this situation, when the second output buffer 102 needs to increase the second source driving signal SD_sig2 according to a next frame signal FRM2, the second output buffer 102 can only use electric charges provided by the intermediate voltage source V_M, and can not use the electric charges previously released by the first output buffer 100. As a result, the electricity is wasted.

As can be seen from the above, the source driver 10 can reuse the electric charges only when the first source driving signal SD_sig1 is increased and the second source driving signal SD_sig2 is decreased. Therefore, the situation that the charge sharing can be applied is limited, and the source driver 10 can not reuse the electric charges and waste the electricity in most situations.

### SUMMARY OF THE INVENTION

A driving device and a driving method utilized in a display device are disclosed, which can improve efficiency of charging sharing and thus save power consumption.

A driving device for a display device is disclosed. The driving device comprises a first output buffer, for generating a first source driving signal at a first output end; a second output buffer, for generating a second source driving signal at a second output end; and an electric charge storage unit, comprising a voltage sensing end coupled to the first output buffer and the second output buffer, for receiving and storing electric charges released by the first output buffer via the voltage sensing end when a level of the first source driving signal decreases, and for outputting the electric charges to the second output buffer via the voltage sensing end when a level of the second source driving signal increases.

A driving method for a display device is disclosed. The driving method comprises receiving and storing electric charges released by a first output buffer via a voltage sensing end, when a level of a first source driving signal decreases; and outputting the electric charges to a second output buffer via the voltage sensing end, when a level of a second source driving signal increases; wherein the first output buffer is used for generating the first source driving signal, and the second output buffer is used for generating the second source driving signal.

A driving device for a display device is disclosed. The driving device comprises a first output buffer, for generating a first source driving signal at a first output end; a second output buffer, for generating a second source driving signal at a second output end; and an electric charge storage unit. The electric charge storage unit comprises an electric charge storage element, coupled to a voltage sensing end, wherein the voltage sensing end is coupled to the first output buffer and the second output buffer; and a voltage regulating unit, coupled to the voltage sensing end, for regulating a voltage level of the voltage sensing end within a predetermined range.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a source driver of an LCD device according to the prior art.

FIG. 2 is a schematic diagram of variations of the source driving signals shown in FIG. 1.

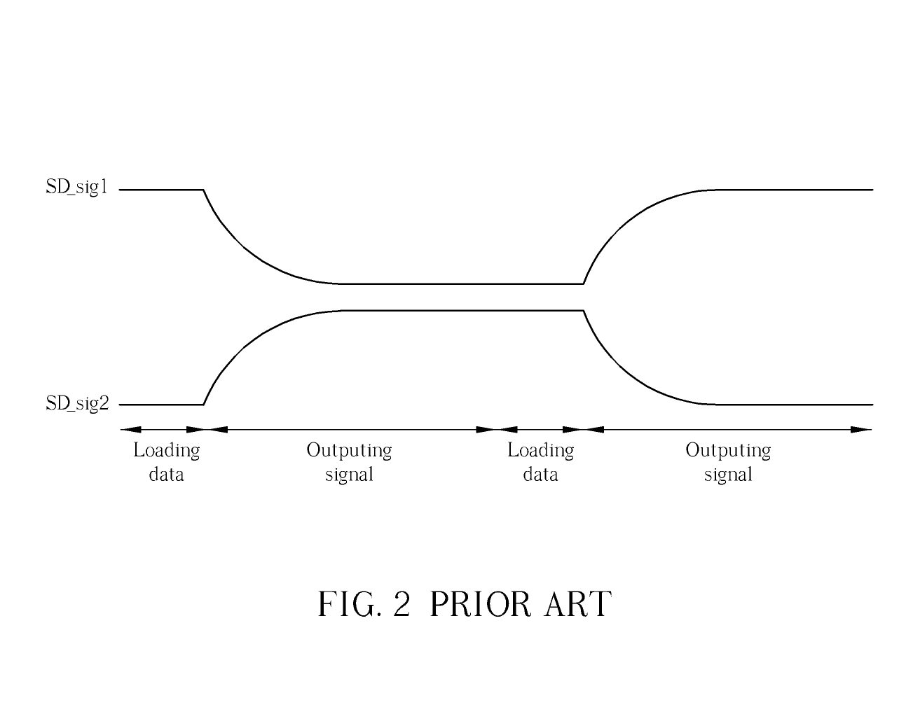

FIG. 3 is a schematic diagram of variations of the source driving signals shown in FIG. 1.

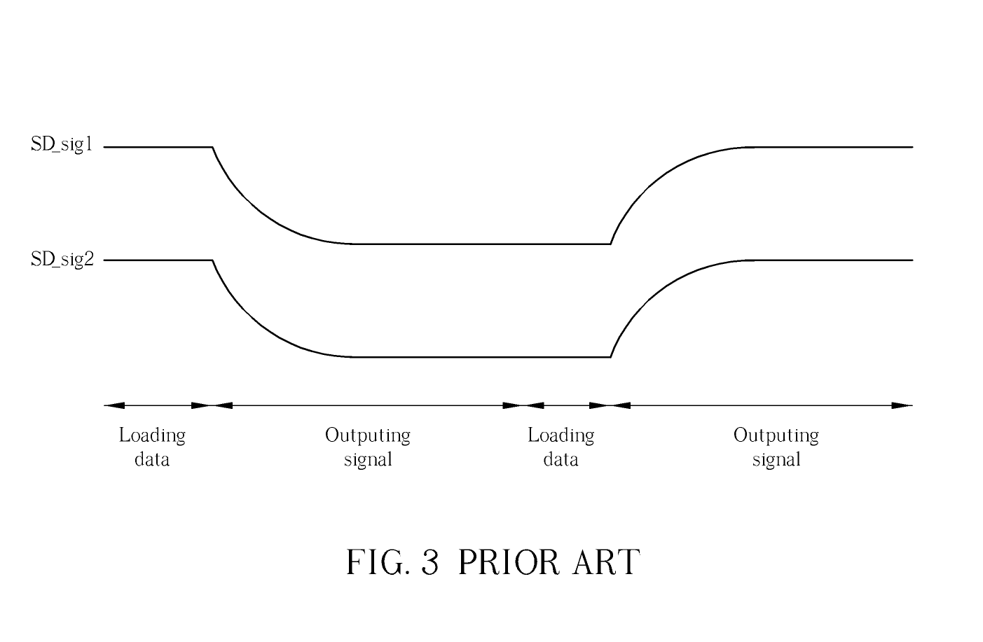

FIG. 4 is a schematic diagram of a source driver of an LCD device according to an embodiment of the present invention.

FIG. 5 is a schematic diagram of an electric charge storage unit according to an embodiment of the present invention.

FIG. 6 is a schematic diagram of different intermediate voltage sources according to an embodiment of the present invention.

FIG. 7 is a schematic diagram of a source driver of an LCD device according to an embodiment of the present invention.

### DETAILED DESCRIPTION

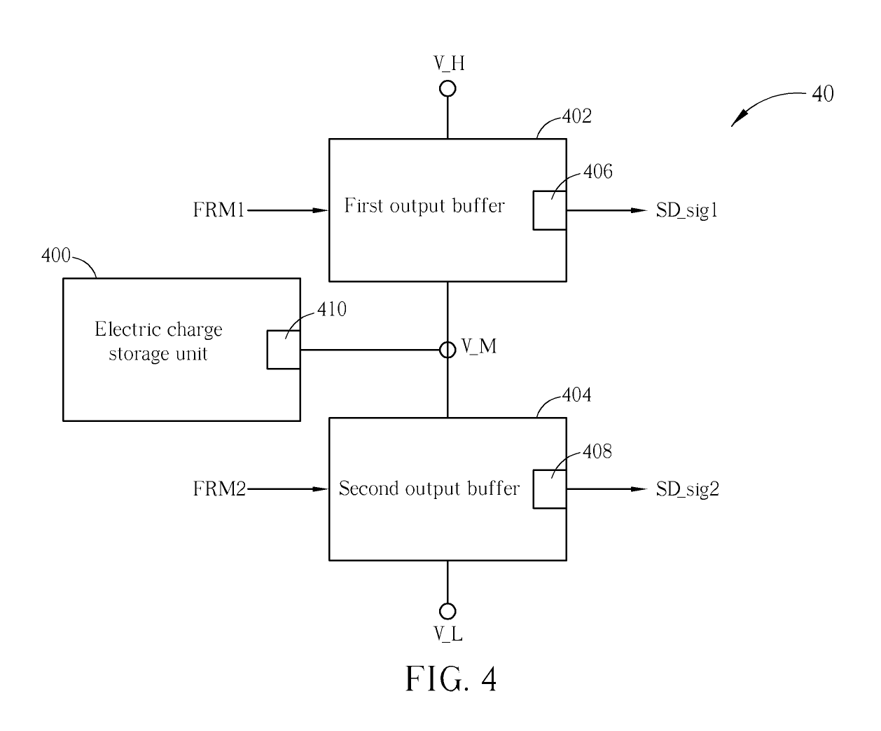

Please refer to FIG. 4, which is a schematic diagram of a source driver 40 of an LCD device according to an embodiment of the present invention. The source driver 40 includes an electric charge storage unit 400, a first output buffer 402 and a second output buffer 404. The first output buffer 402 and the second output buffer 404 include a first output end 406 and a second output end 408, respectively. The electric charge storage unit 400, which includes a voltage sensing end 410, is coupled to the first output buffer 402 and the second output buffer 404 via an intermediate voltage source V_M, for sensing voltage variations of the first output buffer 402 and the second output buffer 404. The electric charge storage unit 400 stores and outputs electric charges according to a sensing result obtained from the voltage sensing end 410. The first output buffer 402 is coupled between a high voltage source V_H and the intermediate voltage source V_M; the second output buffer 404 is coupled between the intermediate voltage source V_M and a low voltage source V_L. The first output buffer 402 uses voltages provided by the high voltage source V_H and the intermediate voltage source V_M, for outputting a first source driving signal SD_sig1 to a panel of the LCD device via the first output end 406, to control operation of pixels of the panel. Similarly, the second output buffer 404 uses the voltages provided by the intermediate voltage source V_M and the low voltage source V_L, for outputting a second source driving signal SD_sig2 to the panel of the LCD device via the first output end 408, to control the operation of the pixels of the panel. Preferably, the first source driving signal SD_sig1 and the second source driving signal SD_sig2 may have the same polarity, or some difference between their phases.

In detail, when the first output buffer 402 needs to release the electric charges to reduce the first source driving signal SD_sig1 according to the frame signal FRM1, for example, in a period when the first source driving signal SD_sig1 and the second source driving signal SD_sig2 are both high, the electric charge storage unit 400 can receive and store the electric charges released by the first output buffer 402 according to the voltage variation of the first output buffer 402 sensed via the voltage sensing end 410. On the other hand, when the second output buffer 404 needs to absorb the electric charges to increase the second source driving signal SD_sig2 according to the frame signal FRM2, for example, in a period when the first source driving signal SD_sig1 and the second source driving signal SD_sig2 are both increased from low to high, the electric charge storage unit 400 can output the stored electric charges to the second output buffer 404 according to the voltage variation of the second output buffer 404 sensed via the voltage sensing end 410, to provide required electric charges. Therefore, the second output buffer 404 can reuse the electric charges released by the first output buffer 402 according to charge sharing provided by the source driver 40, without needing to obtain the required electric charges from the intermediate voltage source V_M. As a result, the electric power can be saved.

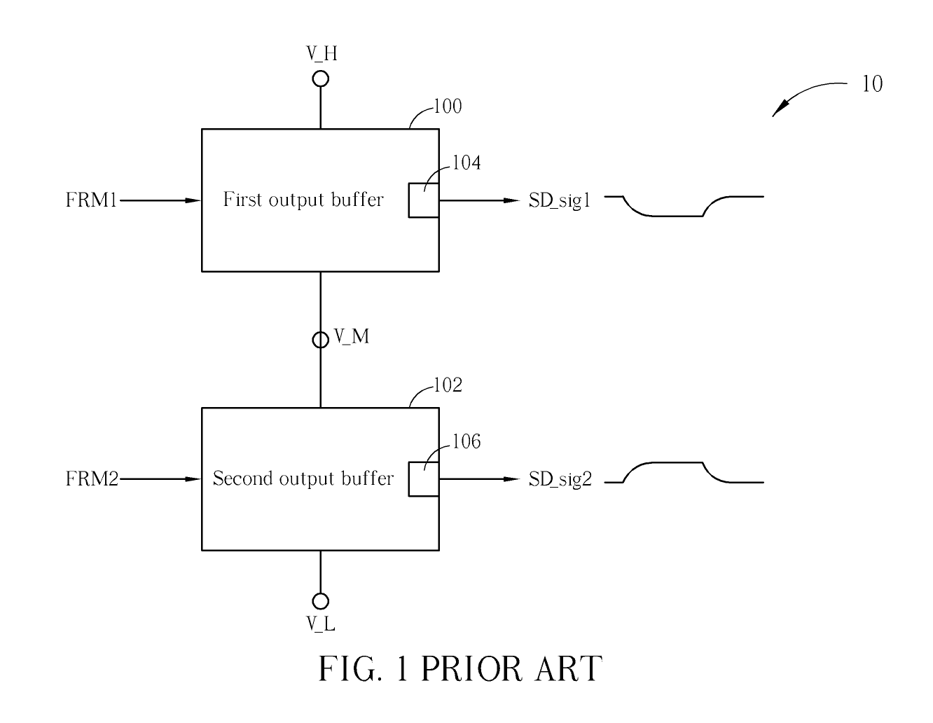

According to the prior art as shown in FIG. 1, when the second output buffer 102 requires electric charges to increase the second source driving signal SD_sig2, the second output buffer 102 can only utilize the electric charges released at the same time by the first output buffer 100. In comparison, the embodiment adds the electric charge storage unit, for storing the electric charges in advance such that the second output buffer 404 can use the electric charges at any time. Therefore, efficiency of the charging sharing is improved, and the electric power can be greatly saved.

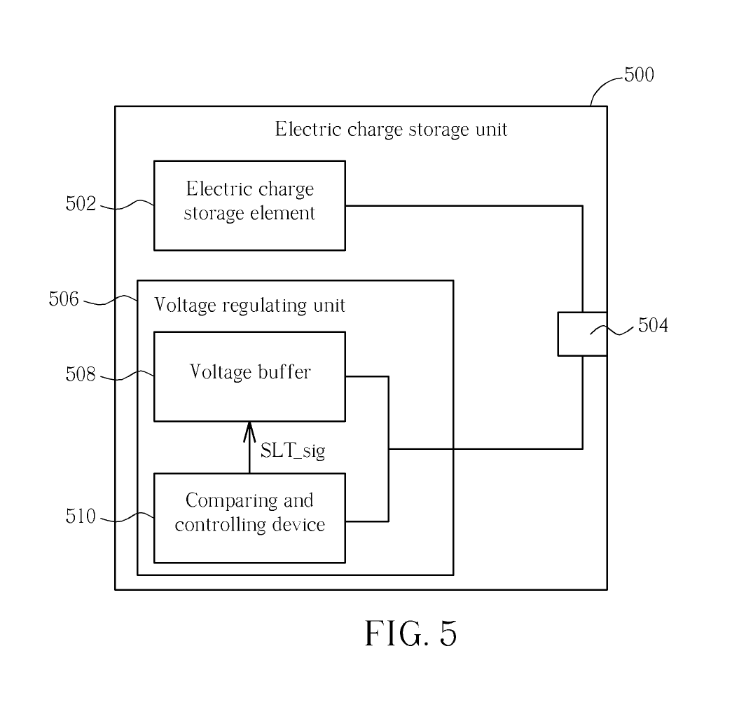

Please note that, in the source driver 40, the electric charge storage unit 400 is used for storing and outputting the electric charges according to a sensing result obtained from the voltage sensing end 410. The electric charge storage unit 400 is not limited to any specific implementation. For example, please refer to FIG. 5, which is a schematic diagram of an electric charge storage unit 500 according to an embodiment of the present invention. The electric charge storage unit 500, which is used for realizing the electric charge storage unit 400 shown in FIG. 4, can include an electric charge storage element 502, a voltage sensing end 504 and a voltage regulating unit 506. Each of the electric charge storage element 502 and the voltage regulating unit 506 is coupled to the voltage sensing end 504 which represents the voltage sensing end 410 shown in FIG. 4. The voltage regulating unit 506 senses voltage variations of the first output buffer 402 and the second output buffer 404 via the voltage sensing end 504, and directs the electric charge storage element 502 to store or output electric charges.

Preferably, the voltage regulating unit 506 includes a voltage buffer 508 and a comparing and controlling device 510. The comparing and controlling device 510 can first compare, via the voltage sensing end 504, the intermediate voltage source V_M with a predetermined high voltage and a predetermined low voltage that define a predetermined voltage range. Then, the comparing and controlling device 510 can generate a selection signal SLT_sig to the voltage buffer 508 according to a comparison result, for controlling the voltage buffer 508, via the voltage sensing end 504, to perform discharging, no operation or charging on the first output buffer 402 and the second output buffer 404 by using the electric charge storage element 502. Besides, the voltage buffer 508 is not limited to any specific implementation as long as it is able to perform charging and discharging on the electric charge storage element 502 according to the selection signal SLT_sig. For example, the voltage buffer 508 preferably includes an output stage including an N-type output transistor and a P-type output transistor coupled in series, wherein gates of the N-type output transistor and P-type output transistor are coupled together for receiving and responding to the selection signal SLT_sig.

Operation of the electric charge storage unit 500 is further illustrated as follows. When the first output buffer 402 decreases the level of the first source driving signal SD_sig1 according to the frame signal FRM1, the first output buffer 402 can release electric charges, causing a voltage of the intermediate voltage source V_M to increase. When the comparing and controlling device 510 detects that the voltage of the intermediate voltage source V_M is higher than the predetermined high voltage, the comparing and controlling device 510 generates the selection signal SLT_sig to the voltage buffer 508, for controlling the voltage buffer 508 to use the electric charge storage element 502 for performing charging via the voltage sensing end 504, so as to absorb the electric charges released by the first output buffer 402. Therefore, the voltage of the intermediate voltage source V_M can decrease back into the predetermined range. On the other hand, when the second output buffer 404 reduces the second source driving signal SD_sig2 according to the frame signal FRM2, the second output buffer 404 can absorb electric charges, causing the voltage of the intermediate voltage source V_M to decrease. When the comparing and controlling device 510 detects that the voltage of the intermediate voltage source V_M is lower than the predetermined low voltage, the comparing and controlling device 510 can generate the selection signal SLT_sig to the voltage buffer 508, for controlling the voltage buffer 508 to use the electric charge storage element 502 for performing discharging via the voltage sensing end 504, so as to output the electric charges to the second output buffer 404. Therefore, the voltage of the intermediate voltage source V_M can increase back into the predetermined range. Besides, when the comparing and controlling device 510 detects that the voltage of the intermediate voltage source V_M is within the predetermined range, the comparing and controlling device 510 can generate the selection signal SLT_sig to the voltage buffer 508, for controlling the voltage buffer 508 to direct the electric charge storage element 502 not to operate, thereby maintaining an original status of no operation, or stopping charging and discharging.

In other words, when the first output buffer 402 or the second output buffer 404 changes the source driving signal, the electric charges moves and the voltage of the intermediate voltage source V_M varies accordingly. When the comparing and controlling device 510 detects that the voltage of the intermediate voltage source V_M is beyond the predetermined range, the selection signal SLT_sig is correspondingly generated, for controlling the voltage buffer 508 to use the electric charge storage element 502 for performing charging, no operation or discharging via the voltage sensing end 504. As a result, when the first output buffer 402 releases the electric charges, the electric charge storage unit 500 is triggered to store the released electric charges in the electric charge storage element 502. Conversely, when the second output buffer 404 requires the electric charges, the electric charge storage unit 500 is triggered to release the stored electric charges to the second output buffer 404. On the other hand, when the first output buffer 402 and the second output buffer 404 stop changing the source driving signals and therefore cause no movement of the electric charges, the pulling-back of the voltage of the intermediate voltage source V_M back into the predetermined range can trigger the electric charge storage unit 500 to stop operation. Therefore, no matter how or when the electric charges of the first output buffer 402 and the second output buffer 404 are varied, the electric charge storage unit 500 can reuse the electric charges and the electric power can be greatly saved accordingly.

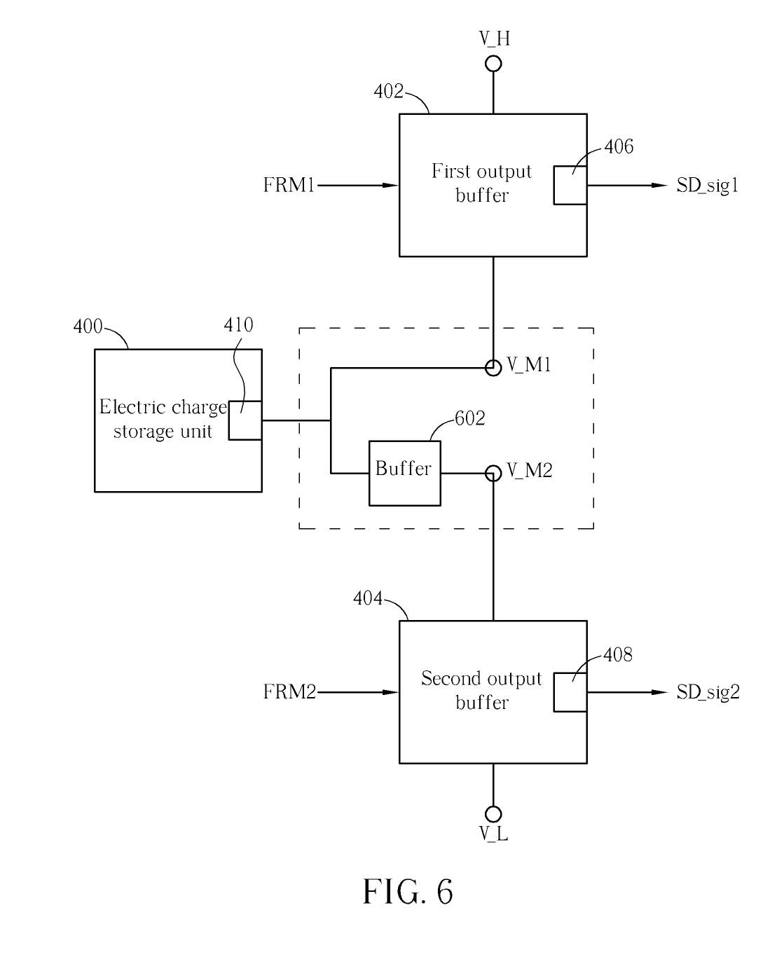

Please note that, the low voltage source V_L of the first output buffer 402 and the high voltage source V_H of the second output buffer 404 shown in FIG. 4 are the same as the intermediate voltage source V_M. However, in practice, those voltage resources can be different according to system requirement or design consideration, e.g., for providing source driving signals with different amplitudes. For example, please refer to FIG. 6, which is a schematic diagram of different intermediate voltage sources V_M1 and V_M2 according to an embodiment of the present invention. Comparing with the embodiment shown in FIG. 4 where the second output buffer 404 is directly coupled to the voltage sensing end 410 and the intermediate voltage V_M is the same for both the first output buffer 402 and the second output buffer 404, the second output buffer 404 in FIG. 6 is coupled to the voltage sensing end 410 via a buffer 602. The buffer 602 is used for storing electric charges and providing a voltage difference between two ends of the buffer 602, further generating a difference between the intermediate voltage source V_M1 and the intermediate voltage source V_M2. Therefore, in the implementation that the source driver 40 reuses the electric charges, the voltages of the intermediate voltage source V_M1 and the intermediate voltage source V_M2 can be different, to an extent determined according to the system requirement, the design consideration, or user configuration, thus improving flexibility of the source driver 40. Furthermore, please also note that the buffer 602 can also be coupled between the first output buffer 402 and voltage sensing end 410 while providing a similar feature.

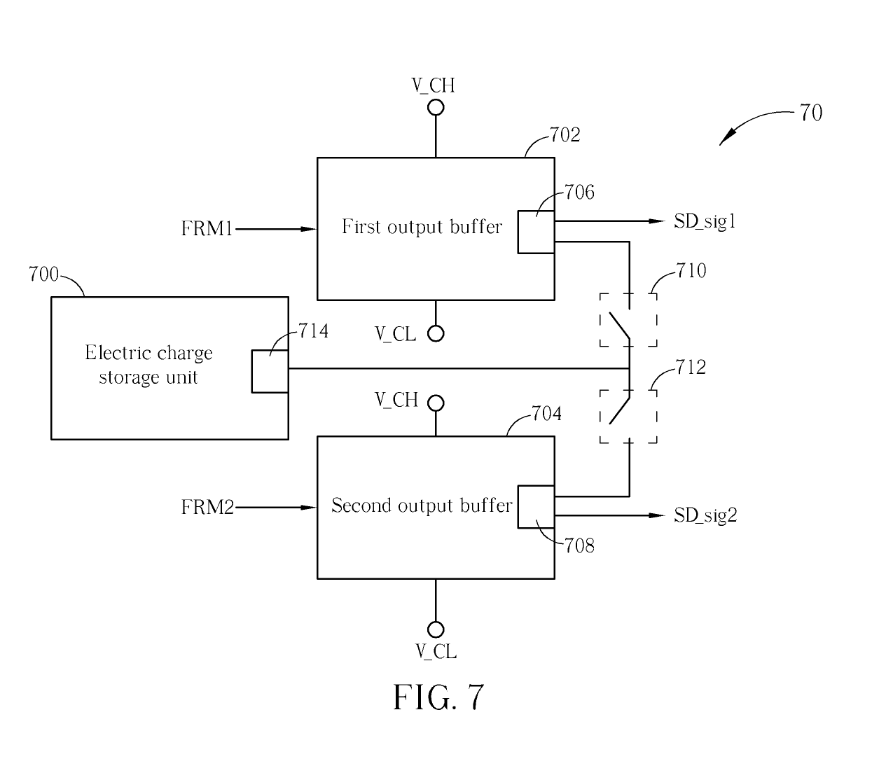

On the other hand, another embodiment of a source driver capable of reusing electric charges is also provided. Please refer to FIG. 7, which is a schematic diagram of a source driver 70 of an LCD device according to an embodiment of the present invention. The source driver 70 includes an electric charge storage unit 700, a first output buffer 702, a second output buffer 704, a first switch device 710 and a second switch device 712. Further, the first output buffer 702 and the second output buffer 704 include a first output end 706 and a second output end 708, respectively. The electric charge storage unit 700 includes a voltage sensing end 714. In detail, the voltage sensing end 714 is coupled to the first output end 706 and the second output end 708 via the first switch device 710 and the second switch device 712, respectively, and is used for sensing voltage variations of the first output end 706 and the second output end 708. The electric charge storage unit 700 controls the first switch device 710 and the second switch device 712 to be turned on or turned off according to a sensing result such that the electric charge storage unit 700 can store and output electric charges via a conductive path established by the first switch device 710 and the second switch device 712. Besides, each of the first output buffer 702 and the second output buffer 704 is coupled between a common high voltage source V_CH and a common low voltage source V_CL. The first output buffer 702 uses voltages provided by the voltage sources V_CH and V_CL, for outputting the first source driving signal SD_sig1 to the panel of the LCD device via the first output end 706, to control the operation of the pixels of the panel. Similarly, the second output buffer 704 uses the voltages provided by the voltage sources V_CH and V_CL, for outputting the second source driving signal SD_sig2 to the panel of the LCD device via the second output end 708, to control the operation of the pixels of the panel.

In detail, when the electric charge storage unit 700 does not operate, the first switch device 710 and the second switch device 712 are controlled to be turned off. When the first output buffer 702 decreases the level of the first source driving signal SD_sig1 according to the frame signal FRM1, the first output buffer 702 needs to release electric charges. In this situation, the voltage sensing end 714 senses a voltage decrease at the first output end 706. Accordingly, the electric charge storage unit 700 controls the first switch device 710 to be turned on and stores the electric charges released by the first output buffer 706. On the other hand, when the second output buffer 704 increases the level of the second source driving signal SD_sig2 according to the frame signal FRM2, the second output buffer 704 needs to absorb electric charges. In this situation, the voltage sensing end 714 senses a voltage increase at the second output end 708. Accordingly, the electric charge storage unit 700 controls the second switch device 712 to be turned on and output the stored electric charges to the second output buffer 708. Therefore, according to charge sharing provided by the electric charge storage unit 700, the second output buffer 704 can reuse the electric charges released by the first output buffer 702 without needing to obtain required electric charges from the common high voltage source VCH, and therefore the electric power can be saved. It can be note that, according to the prior art shown in FIG. 1, when the second output buffer 102 requires electric charges to increase the second source driving signal SD_sig2, the second output buffer 102 can only utilize the electric charges released at the same time by the first output buffer 100. In comparison, the electric charges stored by the electric charge storage unit 700 can be used by the second output buffer 704 at any time according to the embodiment of the present invention. Therefore, efficiency of the charging sharing can be improved, and the electric power can be greatly saved.

Please note that, in the source driver 70, the electric charge storage unit 700 is used for storing and outputting the electric charges according to a sensing result obtained from the voltage sensing end 714, and the detailed structure and operation of the electric charge storage unit 700 is not limited herein. For example, the electric charge storage unit 700 may compare voltages of the first output end 706 and the second output end 708 respectively with a predetermined high voltage and a predetermined low voltage which define a predetermined voltage range, via the voltage sensing end 714. When the electric charge storage unit 700 detects that the voltage of first output end 706 is higher than the predetermined high voltage, the electric charge storage unit 700 can control the first switch device 710 to be turned on and store the electric charges released by the first output buffer 706. Accordingly, the voltage of first output end 706 can decrease back into the predetermined voltage range. Conversely, when the electric charge storage unit 700 detects that the voltage of first output end 706 is lower than the predetermined high voltage, the electric charge storage unit 700 can control the first switch device 710 to be turned off and stop charging. On the other hand, when the electric charge storage unit 700 detects that the voltage of second output end 708 is lower than the predetermined low voltage, the electric charge storage unit 700 can control the second switch device 712 to be turned on and output the stored electric charges to the second output buffer 708. Accordingly, the voltage of second output end 708 can increase back into the predetermined voltage range. Conversely, when the electric charge storage unit 700 detects that the voltage of second output end 708 is higher than the predetermined low voltage, the electric charge storage unit 700 can control the second switch device 712 to be turned off and stop discharging. As a result, no matter how or when the electric charges of the first output buffer 702 and the second output buffer 704 are varied, the electric charge storage unit 700 can reuse the electric charges, and the electric power can be greatly saved accordingly.

Besides, the electric charge storage unit 700 is not limited to any specific implementation. The electric charge storage unit 500 in FIG. 5 can be used for realizing the electric charge storage unit 700, after proper modifications. For example, the comparing and controlling device 510 should be able to execute the above illustrated principle employed by the electric charge storage unit 700. That is, the comparing and controlling device 510 may be able to compare the voltages at the first output end 706 and the second output end 708 respectively with a predetermined high voltage and a predetermined low voltage which define a predetermined voltage range, via the voltage sensing end 504. Moreover, the comparing and controlling device 510 may perform charging and discharging on the electric charge storage element 502 via the voltage buffer 508 according to a comparison result. Furthermore, the comparing and controlling device 510 may be able to control the first switch device 710 and the second switch device 712 to be turned on or off according to the comparison result, such that the electric charge storage unit 502 can store and output electric charges via a conductive path established by the first switch device 710 and the second switch device 712. Details about the functions and operations of the electric charge storage unit 502, the voltage sensing end 504 and the voltage buffer 508 are also similar to the above illustrations, and are not narrated hereinafter for simplicity.

The spirit of the embodiment is to use an electric charge storage unit for storing and outputting electric charges according to voltage variations of a first output buffer and a second output buffer, to save electric power. Modifications and alterations can be made according to any specific requirement, and are not limited to the above illustrations. For example, regarding circuit implementation, the first output buffer, the second output buffer and the voltage buffer stated above are preferably realized by using operational amplifiers. In addition, to increase a response speed of a circuit to the voltage variations, each of the first output buffer and the second output buffer can be realized by an N-type output transistor and a P-type output transistor coupled in series. Moreover, the electric charge storage element can be realized by an operational amplifier and a capacitor. However, embodiments of the present invention are not limited herein. Besides, take the source driver 70 in FIG. 7 as an example, the first switch device 710 and the second switch device 712 can be realized by an N-type switch transistor and a P-type switch transistor, respectively, but are not limited thereto.

Please note that, an LCD device is disclosed for purpose of illustration. Those skilled in the art should readily make modifications or alterations for various kinds of electronic display devices, such as a plasma display device, a cathode ray tube (CRT) display device and a projector, to reduce the power consumption, and embodiments of the present invention are not limited thereto.

To sum up, a driving device and a driving method are provided, which can store and output electric charges according to voltage variations of output buffers and can therefore reduce power consumption.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A driving device for a display device, the driving device comprising:
a first output buffer, for generating a first source driving signal at a first output end;
a second output buffer, for generating a second source driving signal at a second output end; and
an electric charge storage unit, comprising a voltage sensing end coupled to the first output buffer and the second output buffer, for receiving and storing electric charges released by the first output buffer via the voltage sensing end when a level of the first source driving signal decreases, and for outputting the electric charges to the second output buffer via the voltage sensing end when a level of the second source driving signal increases.

2. The driving device of claim 1, wherein the first output buffer is coupled between a high voltage source and an intermediate voltage source, the second output buffer is coupled between the intermediate voltage source and a low voltage source, and the voltage sensing end is coupled to the intermediate voltage source.

3. The driving device of claim 1, wherein the first output buffer is coupled between a high voltage source and a first intermediate voltage source, the second output buffer is coupled between a second intermediate voltage source and a low voltage source, and the driving device further comprises a buffer coupled between one of the first intermediate voltage source and the second intermediate voltage source, and the voltage sensing end.

4. The driving device of claim 1, wherein each of the first output buffer and the second output buffer is coupled to a common high voltage source and a common low voltage source, and the driving device further comprises:
a first switch device, coupled between the first output end and the voltage sensing end; and
a second switch device, coupled between the second output end and the voltage sensing end.

5. The driving device of claim 4, further comprising:
a comparing and controlling device, coupled to the voltage sensing end, for comparing the voltage sensing end with a predetermined high voltage and a predetermined low voltage, and for generating a first switch control signal and a second switch control signal according to a comparison result, to control the first switch device and the second switch device to be turned on or turned off.

6. The driving device of claim 4, wherein each of the first output buffer and the second output buffer comprises an output stage comprising an N-type output transistor and a P-type output transistor coupled in series; the first switch device comprises a P-type switch transistor coupled to the P-type switch transistor of the first output buffer in parallel; and the second switch device comprises an N-type switch transistor coupled to the N-type switch transistor of the second output buffer in parallel.

7. The driving device of claim 1, wherein the electric charge storage unit comprises:
an electric charge storage element, coupled to the voltage sensing end; and
a voltage regulating unit, coupled to the voltage sensing end, for regulating a voltage level of the voltage sensing end within a predetermined range.

8. The driving device of claim 7, wherein the voltage regulating unit comprises:
a comparing and controlling device, coupled to the voltage sensing end, for comparing the voltage sensing end with a predetermined high voltage and a predetermined low voltage, and for generating a selection signal to indicate a comparison result; and
a voltage buffer, coupled between the comparing and controlling device and the voltage sensing end, for performing discharging, no operation or charging on the voltage sensing end according to the selection signal.

9. The driving device of claim 8, wherein the voltage buffer comprises an output stage comprising an N-type output transistor and a P-type output transistor coupled in series, wherein gates of the N-type output transistor and P-type output transistor are coupled to the selection signal.

10. A driving method for a display device, the driving method comprising:
receiving and storing electric charges released by a first output buffer via a voltage sensing end, when a level of a first source driving signal decreases; and
outputting the electric charges to a second output buffer via the voltage sensing end, when a level of a second source driving signal increases;
wherein the first output buffer is used for generating the first source driving signal, and the second output buffer is used for generating the second source driving signal.

11. The driving method of claim 10, further comprising:
controlling each of a first switch device and a second switch device to be turned on or turned off according to a selection signal indicating voltage range of the voltage sensing end;
wherein the first switch device is coupled between the first output buffer and the voltage sensing end, and the second switch device is coupled between the second output buffer and the voltage sensing end.

12. The driving method of claim 11, further comprising:
regulating a voltage of the voltage sensing end within a predetermined range.

13. The driving method of claim 11, wherein regulating the voltage of the voltage sensing end within the predetermined range comprises:
comparing the voltage sensing end with a predetermined high voltage and a predetermined low voltage, and generating a selection signal to indicate a comparison result; and
performing discharging, no operation or charging on the voltage sensing end according to the selection signal.

14. A driving device for a display device, the driving device comprising:
a first output buffer, for generating a first source driving signal at a first output end;
a second output buffer, for generating a second source driving signal at a second output end; and
an electric charge storage unit, comprising:
an electric charge storage element, coupled to a voltage sensing end, wherein the voltage sensing end is coupled to the first output buffer and the second output buffer; and
a voltage regulating unit, coupled to the voltage sensing end, for regulating a voltage level of the voltage sensing end within a predetermined range.

15. The driving device of claim 14, wherein the first output buffer is coupled between a high voltage source and an intermediate voltage source, the second output buffer is coupled between the intermediate voltage source and a low voltage source, and the voltage sensing end is coupled to the intermediate voltage source.

16. The driving device of claim 14, wherein the first output buffer is coupled between a high voltage source and a first intermediate voltage source, the second output buffer is coupled between a second intermediate voltage source and a low voltage source, and the driving device further comprises a buffer coupled between one of the first intermediate voltage source and the second intermediate voltage source, and the voltage sensing end.

17. The driving device of claim 14, wherein each of the first output buffer and the second output buffer is coupled to a common high voltage source and a common low voltage source, and the driving device further comprises:
a first switch device, coupled between the first output end and the voltage sensing end; and
a second switch device, coupled between the second output end and the voltage sensing end.

18. The driving device of claim 14, wherein the voltage regulating unit comprises:
a comparing and controlling device, coupled to the voltage sensing end, for comparing the voltage sensing end with a predetermined high voltage and a predetermined low voltage, and for generating a selection signal to indicate a comparison result; and
a voltage buffer, coupled between the comparing and controlling device and the voltage sensing end, for performing discharging, no operation or charging on the voltage sensing end according to the selection signal.

19. The driving device of claim 14, wherein the electric charge storage element receives and stores electric charges released by the first output buffer via the voltage sensing end when a level of the first source driving signal changes towards a first direction, and outputs the electric charges to the second output buffer via the voltage sensing end when a level of the second source driving signal changes towards a second direction.
